(19) United States
(12) Patent Application Publication
(10) Pub. No.: US 2002/0135275 A1
(43) Pub. Date: Sep. 26, 2002

(54) Piezoelectric actuator

(76) Inventors: Rudolf Heinz, Renningen (DE); Bertram Sugg, Gerlingen (DE); Steffen Jung, Leonberg (DE)

Correspondence Address: RONALD E. GREIGG, GREIGG & GREIGG P.L.L.C., 1423 POWHATAN STREET, UNIT ONE, ALEXANDRIA, VA, 22314, US

(21) Appl. No.: 10/031,788

(22) PCT Filed: Apr. 5, 2001
(86) PCT No.: PCT/DE01/01328

(30) Foreign Application Priority Data
Mar. 25, 2000 (DE) 100 26 005.5

(51) Int. Cl. H01L 41/047

(52) U.S. Cl. 310/366

(57) ABSTRACT

A piezoelectric actuator, for instance for actuating a mechanical component, is proposed that has a multilayer structure of piezoelectric layers and disposed between them inner electrodes (2, 3) and an alternate-side lateral contacting of the inner electrodes (2, 3) via outer electrodes (4, 5). The outer electrodes (4, 5) are applied in network- or fabric-like fashion, each distributed over one side face, and are contacted at least at some points to the respective inner electrodes (2, 3). The outer electrodes (4, 5) are lengthened past the multilayer structure of piezoelectric layers in such a way that the delivery of the electrical voltage takes place at the extensions (8, 9).

### PRIOR ART

The invention relates to a piezoelectric actuator, for instance for actuating a mechanical component such as a valve or the like, as generically defined by the characteristics of the preamble to the main claim.

It is widely known that by utilizing what is known as the piezoelectric effect, a piezoelectric element can be constructed from a material of a suitable crystalline structure. When an external electrical voltage is applied, a mechanical reaction of the piezoelectric element ensues, which as a function of the crystalline structure and the regions where the electrical voltage is applied takes the form of a pressure or tension in a predeterminable direction. The construction of this piezoelectric actuator can be done in a plurality of layers (multilayer actuators), in which the electrodes by way of which the electrical voltage is applied are each disposed between the layers.

Such piezoelectric actuators can be provided for instance for driving switching valves in fuel injection systems of motor vehicles. In operation of the piezoelectric actuator, care must be taken in particular to assure that mechanical stresses in the layer construction not cause any problematic development of cracks in the region of the outer connection electrodes. Since the inner electrodes, each contacted on one side, are integrated in comblike fashion with the layer structure, the successive electrodes in the direction of the layer structure must each be contacted on opposite sides in alternation.

Upon an actuation of the piezoelectric actuator, that is, when a voltage is applied between the opposed inner electrodes in the layer structure, different mechanical forces occur in the region of the inner electrodes and in the region of the contactings on the outer electrodes, and these can cause mechanical stresses and hence cracks in the outer electrodes. The outer electrodes must then in turn be provided with connection electrodes, which as a rule must also withstand mechanical stresses.

### ADVANTAGES OF THE INVENTION

The piezoelectric actuator described at the outset, which can for instance be used to actuate a mechanical component, is advantageously embodied in such a way that at least one layer of the applicable outer electrode is constructed in network- or fabric-like fashion, distributed each over a respective side face, and is contacted at least at some points to with the applicable inner electrodes. The network- or fabric-like outer electrodes are lengthened beyond the multilayer structure of piezoelectric layers in such a way that at the extensions, the delivery of the electrical voltage takes place via suitable terminals.

Compared to typical soldering of these external terminal wires directly to the outer electrode near the foot of the piezoelectric actuator in the active or inactive region, according to the invention it is advantageously attained that upon the connection to the extension of the outer electrode, an improved and mechanically sturdier contacting is established. In the typical soldering to the network- or screen-like fabric, the adhesion of the electrodes to the piezoelectric actuator is only very slight, so that even slight forces can cause the outer electrode to peel off from the piezoelectric actuator. According to the invention, the number of electrical connections required in the region of the multilayer structure can then be reduced as well.

Because the outer electrodes are lengthened beyond the piezoelectric actuator foot, and in the ideal case as far as the plug, they can accordingly be contacted in a noncritical region. Furthermore, on the one hand this makes economical production possible, and on the other it reduces the process risk and the risk of failure at that point. Another advantage is that an additional inactive region that may otherwise be necessary on the multilayer structure for contacting purposes can be dispensed with, which makes a shorter structural length possible and makes further cost savings possible.

In a preferred embodiment, the extensions are guided in an electrically insulated way by the foot part, for instance comprising steel or Al₂O₃ of the piezoelectric actuator, at which part the multilayer structure of piezoelectric layers is secured. In this respect, it is also advantageous if the extensions, for the sake of fixation and tension relief of the outer electrodes, are retained in a potting composition, which is introduced into a recess of the foot part, optionally surrounded by a shaped part of steel or polymer.

The extensions can advantageously also be realized by having the outer electrodes tapered in the region of the extensions. The outer electrodes can also be folded or coiled in the region of the extensions.

In a simple way, the network- or fabric-like outer electrodes can comprise crossed horizontally and vertically laid wires, or wires laid at an incline of 45°, which are contacted to one another by copper- or tin-plating.

These and other characteristics of preferred refinements of the invention can be learned not only from the claims but also from the description and the drawings; the individual characteristics can each be realized on their own or multiple characteristics can be realized in the form of subsidiary combinations both in the embodiment of the invention and in other fields and can represent both advantageous and intrinsically patentable embodiments for which patent protection is here claimed.

### DRAWING

Exemplary embodiments of the piezoelectric actuator of the invention will be explained in conjunction with the drawing. Shown are:

FIG. 1, a section through a piezoelectric actuator with a multilayer structure of layers of piezoceramic and inner electrodes, as well as a netlike outer electrode lengthened by a foot part;

FIG. 2, a section taken along the line A-A in the exemplary embodiment of FIG. 1;

FIG. 3, a detail in section in the region of the leadthrough of the lengthened outer electrode through the foot part;

FIG. 4, a modification of the example in FIGS. 1-3, with an additional shaped part in the region of the extensions;

FIG. 5, a modification of the preceding examples, with a tapered outer electrode in the extension;

FIG. 6, an exemplary embodiment with an outer electrode that is folded in the extension;

FIG. 7, an exemplary embodiment with an outer electrode that is coiled in the extension;

FIGS. 8 and 9, exemplary embodiments of the network- or fabric-like outer electrodes; and

FIG. 10, a detail in section through the copper-plated or tin-plated wires of the network- or fabric-like outer electrode.

### DESCRIPTION OF THE EXEMPLARY EMBODIMENTS

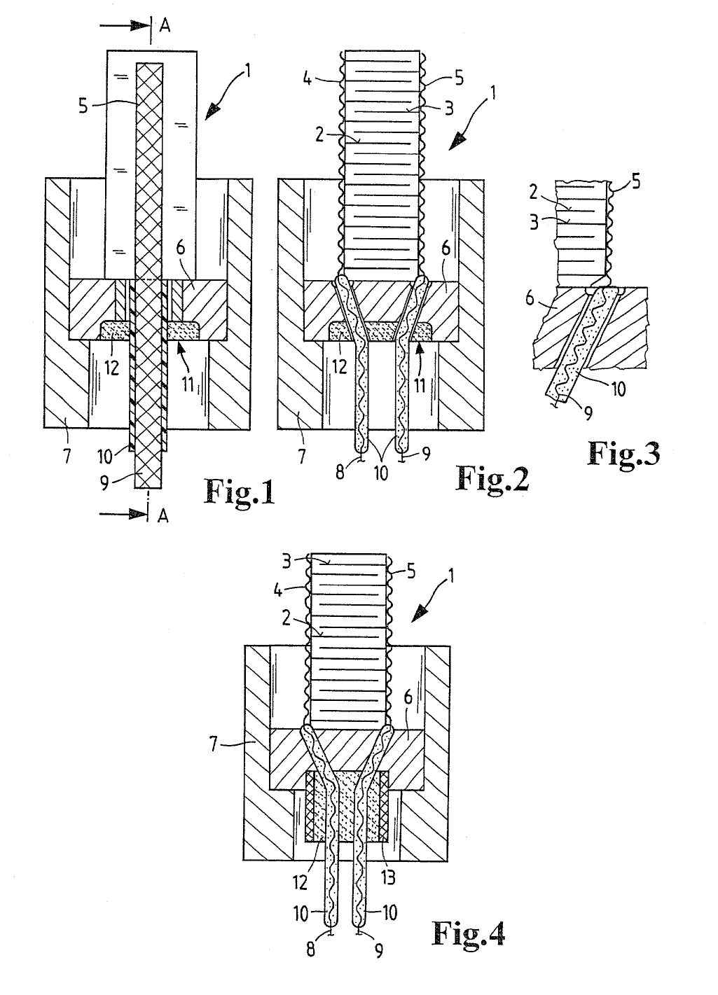

In FIGS. 1 and 2, in various sections, a piezoelectric actuator 1 is shown, which is constructed in a manner known per se of piezoelectric sheets of a ceramic material of a suitable crystalline structure, so that by utilizing the so-called piezoelectric effect, upon application of an external electrical voltage to inner electrodes 2 and 3, each via outer electrodes 4 and 5, a mechanical reaction of the piezoelectric actuator 1 in the axial direction ensues.

The piezoelectric actuator is firmly embedded, via a foot part 6, in a housing 7, such as the housing of an injection valve for motor vehicles. The outer electrodes 4 and 5 have extensions 8 and 9, on each of whose lower end a respective electrical terminal for a voltage supply can be mounted. In the region of the leadth rough of the extensions 8 and 9 through the foot part 6 and optionally beyond it, the extensions 8 and 9 are electrically insulated, for instance by means of a shrink-fitted hose 10. For fixation and tension relief of the outer electrodes 4 and 5, or extensions 8 and 9, these elements are sheathed with a potting composition 12 in a recess 11 of the foot part 6. In FIG. 3, the region of the leadthrough of the extensions 8 and 9 is shown in detail in terms of one exemplary embodiment.

An exemplary embodiment of FIG. 4 shows a modification for fixation and tension relief of the outer electrodes 4 and 5, or extensions 8 and 9, with a shaped part 13, located in the foot part 6, into which shaped part the potting composition 12 is fitted.

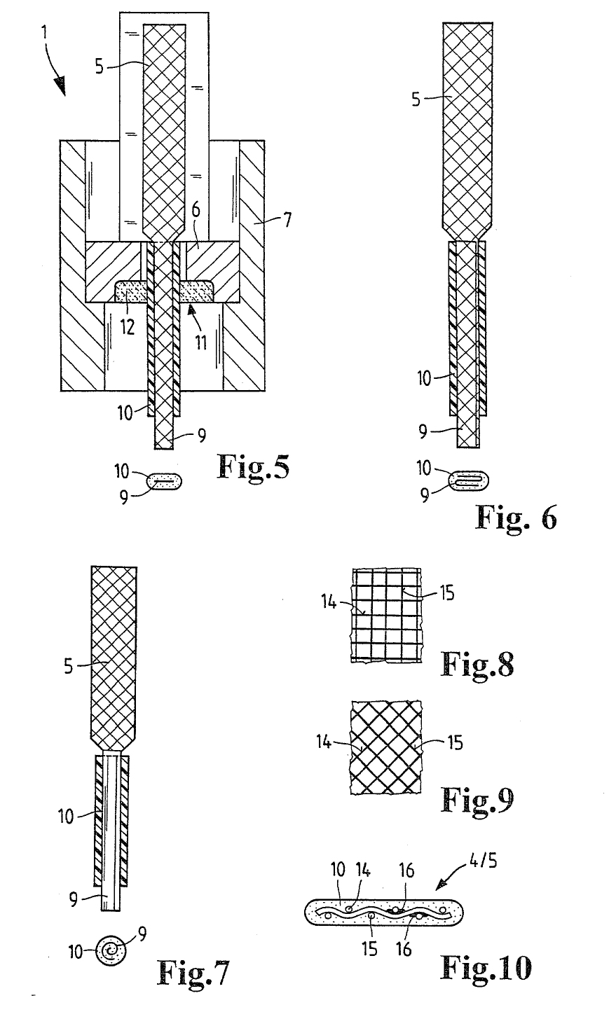

Various exemplary embodiments of the electrode extensions 8 and 9 are shown in FIGS. 5-7. In FIG. 5, the extensions 8 and 9 are merely tapered, which can also be learned from the cross section at the bottom of the extension 9. FIG. 6 shows an extension 9 which is folded, and FIG. 7 shows an extension 9 that is coiled, which again can be learned from the cross sections shown below of the extension 9.

In FIG. 8, a netlike construction of the outer electrode 4 or 5 with horizontally and vertically extending wires 14 and 15 can be seen, and FIG. 9 shows a comparable structure with wires 14 and 15 inclined by 45°. In the sectional view of FIG. 10, the location of the crossed wires 14 and 15 can be seen, with contact points 17, made for instance by copper-plating or tin-plating of the wires 14 and 15.

1. A piezoelectric actuator, having
a multilayer structure of piezoelectric layers and inner electrodes (2, 3) disposed between the piezoelectric layers;
an alternate-side lateral contacting of the inner electrodes (2, 3) via outer electrodes (4, 5), via which an electrical voltage can be delivered; wherein
the outer electrodes (4, 5) are applied, each distributed over one side face, in the form of a network or fabric and are each contacted at least at some points to the respective inner electrodes (2, 3), and between the contact points a stretchable region comes to rest; and wherein
the network- or fabric-like outer electrodes (4, 5) are lengthened beyond the multilayer structure of piezoelectric layers in such a way that the delivery of the electrical voltage is effected at the extensions (8, 9).

2. The piezoelectric actuator of claim 1, characterized in that
the extensions (8, 9) are guided, electrically insulated (10), by a foot part (6) of the piezoelectric actuator (1), to which part the multilayer structure of piezoelectric layers is secured.

3. The piezoelectric actuator of claim 2, characterized in that
the extensions (8, 9) are held in a potting composition (12), which is introduced into a recess (11) of the foot part (6).

4. The piezoelectric actuator of claim 3, characterized in that
the potting composition (12) is surrounded by a shaped part (13).

5. The piezoelectric actuator of one of the foregoing claims, characterized in that
the outer electrodes (4, 5) are tapered in the region of the extensions (9, 10).

6. The piezoelectric actuator of one of claims 1-4, characterized in that
the outer electrodes (4, 5) are folded in the region of the extensions (8, 9).

7. The piezoelectric actuator of one of claims 1-4, characterized in that
the outer electrodes (4, 5) are coiled in the region of the extensions (8, 9).

8. The piezoelectric actuator of one of the foregoing claims, characterized in that
the network- or fabric-like outer electrodes (4, 5) comprise crossed wires (14, 15) laid at an incline of 45°.

9. The piezoelectric actuator of one of the foregoing claims, characterized in that
the network- or fabric-like outer electrodes (4, 5) comprise crossed wires (14, 15) laid horizontally and vertically.

10. The piezoelectric actuator of one of claims 8 or 9, characterized in that
the wires (14, 15) are contacted to one another by being copper- or tin-plated to one another.
